(19) United States
(12) Patent Application Publication
(10) Pub. No.: US 2026/0169393 A1
(43) Pub. Date: Jun. 18, 2026

(54) METHOD AND APPARATUS FOR CORRECTING AN OPTICAL ELEMENT WITH INHOMOGENEOUS MATERIAL PROPERTIES

(71) Applicants: Carl Zeiss SMT GmbH, Oberkochen (DE); Carl Zeiss SMS Ltd., D.N. Misgav (IL)

(72) Inventors: Alberto Eljarrat Ascunce, Berlin (DE); Martin van Driel, Munich (DE); Vladimir Dmitriev, Tsurit (IL); Jonas Umlauft, Regensburg (DE); Markus Seesselberg, Aalen (DE)

(21) Appl. No.: 19/424,530

(22) Filed: Dec. 18, 2025

(30) Foreign Application Priority Data
Dec. 18, 2024 (EP) 24221119.1

(51) Int. Cl. G03F 7/00

(52) U.S. Cl. CPC G03F 7/70516; G03F 7/70504

(57) ABSTRACT

A method, a computer program, and an apparatus for correcting an error of a mask substrate using a plurality of laser pulses applied on a plurality of positions on the mask substrate is provided.

The method comprises:
receiving a refractive index map of the mask substrate,
receiving mask substrate error information,
determining at least one first laser parameter for each of the plurality of laser pulses and/or the plurality of positions,
wherein the determining is based on the refractive index map and the mask substrate error information.

### CROSS-REFERENCE TO RELATED APPLICATIONS

The present application claims priority to European patent application with application Ser. No. 24/221,119.1, filed on Dec. 18, 2024, the entire contents of which are expressly incorporated herein by reference.

### TECHNICAL FIELD

The present invention generally relates to the field of correcting an error of a mask using a plurality of laser pulses, wherein a substrate of the mask may have inhomogeneous material properties. Specifically, the laser pulses may locally deform the substrate of the mask such that bending errors and/or positioning errors of pattern elements and/or other elements on the mask may be corrected. The aspects may, for example, be applied to masks of EUV, DUV or generally optical lithography masks, nanoimprint lithography templates or other elements, such as masks or mask substrates in general, wafers, etc., e.g., to correct bending errors and/or positioning errors on the substrates, wafers, etc.

### BACKGROUND

As a result of a constantly increasing integration density in the semiconductor industry, masks must project smaller and smaller structures onto a photosensitive layer, e.g., a photoresist on wafers. To fulfil this demand, the exposure wavelength of masks has been shifted to smaller wavelengths, and in particular to the extreme ultraviolet (EUV) wavelength range of the electromagnetic spectrum (e.g., in the range of 10 nm-15 nm).

Particularly, for these short wavelength ranges, masks must fulfil highest demands with respect to, e.g., phase or amplitude errors, planarity, etc. The tolerable deviation of their substrates from the planarity is only a portion of a wavelength of the exposure wavelength to not significantly disturb the phase front of the electromagnetic wave reflected from a multi-layer structure on a surface of the substrate. Larger deviations may lead to variations of the optical intensity distribution in the photoresist due to a constructive or a destructive superposition of the wavefront in the photoresist. Similarly, placement errors of pattern elements may lead to errors, even if the errors are minor.

Due to both manufacturing costs and quality requirements, it is desirable to repair or modify masks, for example, by increasing the planarity or correcting positions of pattern elements. To this end the application of laser pulses has been used for correcting masks. While the approaches used so far have proven as extremely powerful tools for repair, there is a desire to render these approaches even more robust and even more precise to expand the possible range of errors that may be corrected.

### SUMMARY

The above desire is met at least in part by the examples outlined herein.

In a first example, a method for correcting an error of a mask using a plurality of laser pulses applied on a plurality of positions on the substrate of the mask is provided. The method comprises receiving a refractive index map of the substrate of the mask. The method further comprises receiving mask error information. The method may further comprise determining at least one first laser parameter for each of the plurality of laser pulses and/or the plurality of positions. The determining may be based on the refractive index map and the mask error information.

For example, the determining may comprise the following steps: First, the mask error information may be analyzed to identify regions requiring correction and the magnitude of deformation needed at each region. The refractive index map may then be used to predict how laser pulses will propagate through the substrate at each position, accounting for local refractive index variations. An optimization algorithm may be employed that considers both the desired correction from the mask error information and the predicted pulse behavior from the refractive index map. The algorithm may iteratively optimize laser parameters such as pulse energy, pulse duration, focal depth, numerical aperture, and/or beam shape until a combination is found that achieves the desired correction while compensating for refractive index inhomogeneities. In some examples, the optimization may use a cost function that minimizes the difference between the predicted outcome and the desired correction specified in the mask error information.

Basing the determining step on the refractive index map may have the advantage that the correctional measures by the laser pulses take into account the effect of local variations of the refractive index of the substrate of the mask on the laser pulses. It has indeed turned out that the precision of the known approaches is so advanced that, in some cases, it is limited by (even minute) variations in the refractive index of a mask substrate that has previously been seen as a medium with a level of homogeneity in its refractive index. By using the (intrinsic) local variations of the refractive index as an input for determining, e.g., optimized pulse positions and/or parameters, the repair can be even more precise and tailored to the individual mask substrate and the varying refractive index variations that these may have.

The local variations of the refractive index may be taken into account when determining (optimized) positions for the laser pulses. For example, a distance between adjacent laser pulses may be varied depending on the local refractive index (variation) at the region of the two adjacent laser pulses.

In yet other examples, the local variations may be taken into account when determining the laser parameters. For example, a desired correction for the mask error may be achieved with a certain focal shape of a pulse at a certain position, which may however be deformed from its intended shape by local refractive index variations (e.g., leading to a lens effect, an astigmatism, coma, etc.). By taking into account this variation, e.g., by the refractive index map, the focal shape may be adjusted locally, such that despite the local refractive index variations, the actual laser pulse arriving in the substrate has the desired focal shape and may thus generate the desired local deformation.

A map, for example, the refractive index map of the substrate of the mask, may generally ascribe the substrate of the mask with at least two refractive index values at least at two different positions. In some examples, it may comprise a plurality of refractive index values for a plurality of positions, e.g., on a regular grid. In some examples, the refractive index map may be a two-dimensional map, e.g., as a function of coordinates on the surface of the substrate. This may lead to good results, when the substrate of the mask shows little variation of the refractive index with the depth of the material. In other examples, the map may be a three-dimensional map, also for example being a function of a depth within the substrate.

The mask error information may comprise deformation information and/or alignment information, for example, alignment information relating to a pattern (e.g., of pattern elements) on the substrate of the mask's surface. The error information may be provided in form of a scalar and/or a vector field, for example, describing geometric deviations of the mask or the substrate of the mask compared to an ideal or desired form. It may be local error information in form of a 2D and/or a 3D map. The deformation may, for example, be disadvantageous in terms of on-product overlay (OPO) which may be a measure of how well different layers of a chip are aligned between each other. Also, the deformation may concern a spacing of features in one layer which may need to be corrected, e.g., such as to ensure uniformity of critical dimension.

Methods for correcting an error of a mask are for example known from DE 10 2011 083 774 A1 and WO 2013/030820 A1 which are incorporated by reference in their entirety herein. As described in these references, using a plurality of laser pulses applied on a plurality of positions on the substrate of the mask may allow to at least partially correct mask errors. To this end, the plurality of positions and/or laser parameters, for example, the first laser parameter, can be selected based on the mask errors.

Laser parameters, for example, the at least one first laser parameter, may be properties of the laser pulse, for example, number of pulses, pulse duration, pulse power, pulse polarization, numerical aperture, beam shape on the substrate of the mask, focal depth, etc. The plurality of positions may be defined as lateral positions on the substrate of the mask, e.g., as (x, y) coordinates on the substrate of the mask. The positions may be 2D dimensional positions, wherein a first plurality of positions may be associated with a first focal depth, a second plurality of positions may be associated with a second focal depth, etc. (also referred to as writing depth). In some examples, the plurality of positions may be defined in terms of respective densities of laser pulses per area cell of the substrate of the mask. An area cell may be an area unit into which the substrate of the mask is conceptually divided.

The method may comprise: applying the plurality of laser pulses with the at least one first laser parameter for each pulse on the plurality of positions on the substrate of the mask. Applying the plurality of laser pulses may have the effect that the error of the mask, as described by the mask error information, is at least partially corrected. Specifically, each laser pulse may induce a local deformation, wherein all local deformations together lead to the desired error correction. The quality of this correction may be improved compared to other methods which do not take the refractive index map into account.

The method may comprise receiving at least one second laser parameter for each of the plurality of laser pulses. The at least one first laser parameter and/or the plurality of positions may be further determined based on the at least one second laser parameter. In some examples, the at least one second laser parameter may comprise a focal depth of a pulse (assuming a homogenous refractive index medium), a numerical aperture of a pulse, a pulse diameter and/or shape on the substrate surface, a focal shape (assuming a homogeneous refractive index medium). The at least one second laser parameter may in some examples be a fixed parameter that is used for determining the at least one first laser parameter and/or the plurality of positions.

For example, the at least one second laser parameter may be used to determine the at least one first laser parameter and/or the plurality of positions based on the at least one second laser parameter as follows: For instance, if the second laser parameter specifies a pulse diameter, the first laser parameter, e.g., a pulse power may be adjusted based on a model that predicts the modification of the refractive index map of the substrate of the mask due to applying of laser pulses with the first and second laser parameter.

In some examples, the at least one second laser parameter may be the same for each of the plurality of pulses. For example, it may not be based on the refractive index map. In some examples, the at least one second laser parameter may be determined based at least in part on the mask error information, e.g., such as to optimize repair (assuming a homogeneous refractive index). The latter may allow using known techniques for determining the at least one second laser parameter, e.g., assuming a homogeneous medium. The method may then allow subsequently optimizing positions and/or the first laser parameters based on the refractive index map. For example, the optimization based on the refractive index map may proceed as follows: For each candidate position on the substrate, the local refractive index variation may be extracted from the refractive index map. Using ray-tracing or wave propagation modeling, the effect of this local variation on the laser pulse may be calculated, determining how the pulse's focal shape, focal position, and/or intensity distribution will be altered. Based on this calculation, the laser parameters may be adjusted to compensate for these alterations. For example, if the local refractive index causes defocusing, the pulse focal depth may be adjusted accordingly. This will be detailed with respect to a representation using Zernike polynomials below, but other representations are possible as well. Notably, the at least one first laser parameter may comprise the at least one second laser parameter, wherein a value assigned to that at least one second laser parameter is altered/optimized when determining the at least one first laser parameter. In other examples, the at least one second laser parameter may be fixed, and the at least one first laser parameter that is determined relates to a different parameter.

Additionally or alternatively, the method may comprise receiving a second plurality of positions on the substrate of the mask. The second plurality of positions may be determined based on the mask error information. The second plurality of positions may not depend on the refractive index map. The plurality of positions and/or the at least one first laser parameter may be determined based on the second plurality of positions. For example, the second positions may be the result of an optimization based on known techniques that do not take into account the refractive index map. The first positions may then be determined, e.g., using the second positions as a starting point for optimization. In other examples, the second positions may be kept fixed as the first positions and merely the at least one first pulse parameter may be determined such as to optimize the repair based on the refractive index map.

Not taking into account the refractive index map when determining the at least one second laser parameter and/or the second plurality of positions may have the advantage that the computational effort that may be needed for the determination may be reduced. Using the at least one second laser parameter and/or the second plurality of positions for determining the at least one first laser parameter and/or the plurality of positions may have the advantage that the determining the at least one first laser parameter and/or the plurality of positions may be simplified. As outlined, in some examples, the at least one second laser parameter and/or the second plurality of positions is used as a starting point for determining the at least one first laser parameter and/or the plurality of positions.

Determining the at least one first laser parameter may further comprise determining, for each position of the plurality of positions and/or of the second plurality of positions, a local optical path difference, OPD, wherein the local OPD is caused by deviations in the refractive index map from an average refractive index of the substrate of the mask. Describing the variations of the refractive index in terms of a local optical path difference, OPD, may simplify the description of the underlying physical problem and allow for easier corrections. This will be further detailed below. For example, for a grid of potential positions, an OPD may be determined which can then be used to determine the impact of the local refractive index variation on a pulse applied at that position, e.g., on the focal shape and/or focal position (e.g., a deviation from an ideal focal shape and/or focal position expected for a perfectly homogenous medium). In other words, based on the OPD, a suited compensation for the laser parameter(s), for example, the first and/or the second laser parameter may be performed. This may result in propagation of the pulse so that the pulse propagates through an area with existing OPD in a propagation similar to an uncompensated laser in the case of zero or near-zero OPD. As a simple example, if the OPD leads to a focal shift, the focal shift may be pre-compensated so that the resulting pulse does not exhibit the focal shift. This may then be used in an optimization to vary the pulse properties and/or positions such as to achieve overall optimization of the repair.

Determining the local OPD may include raytracing of a laser pulse to be applied on the respective position based on the refractive index map.

For example, the OPD at a given position x, y may be determined based at least in part on the formula

$$OPD ( x , y ) = \int Δ n ( x , y ) ds ,$$

wherein n₀ is an average refractive index of the substrate of the mask, Δn is the refractive index map describing the deviation of the local refractive index from the average refractive index and wherein the differential ds is the differential along the ray path obtained via raytracing of the laser pulse.

This may allow to take the propagation of the laser pulse and the refractive index observed by the laser pulse while propagating through the substrate of the mask into account. In some examples, a high accuracy of the description may be achieved when describing the refractive index map in two dimensions. In some examples, homogeneity of the refractive index for a depth coordinate of the substrate of the mask may be assumed. In other examples, a three-dimensional refractive index map may be used for ray-tracing. For each position, the determining of the local OPD may include integrating the local phase difference for a plurality of local pulse coordinates around a center of each pulse, acquired by propagation from that local pulse coordinate to a corresponding focal depth z₀ within the substrate of the mask. For example, a pulse may comprise a Gaussian shape when impinging on the substrate of the mask surface. For example, two local coordinates may define a position within the Gaussian pulse on the surface. For each position, the refractive index map may be integrated to the (planned) focus of the pulse in a certain focal depth z₀. Hence, for each local coordinate on the surface, a corresponding OPD may be determined. For the calculation, for example, a grid of coordinate pairs may be used, e.g., a rectangular grid, a circular grid. In general, a grid may follow the shape of the pulse cross-section, such as elliptical, etc.

Using local pulse coordinates may have the advantage that the description of the problem may be simplified. Further, using this description may simplify compensating the effect of the refractive index inhomogeneity of the substrate of the mask by an apparatus. In some examples, the integrating may use a two-dimensional refractive index map.

In other examples, the refractive index map may also include the contribution of the average refractive index. In further examples, other coordinate systems may be used. According to an aspect, the integration for a certain local coordinate to the focus depth takes into account the path of a ray on its way from the local coordinate to the focus depth.

Each local OPD may comprise a set of decomposition weights for Zernike polynomials. Using decomposition weights for Zernike polynomials may simplify the description of the problem. For example, instead of using the full local OPD map for each pulse position in the optimization process, only a few (lowest order) decomposition weights may be used for each pulse position, drastically reducing computational efforts. In other examples, other polynomials and/or vector spaces than Zernike polynomials may be used.

If the effect due to refractive index variations at a given position is known in terms of coefficients for Zernike polynomials, this may simplify compensation of a laser beam. For example, a configuration of correction optics, such as a pulse shaping unit, based on coefficients of Zernike polynomials may be simplified and/or yield improved results. The decomposition weights for the Zernike polynomials for each position of the plurality of positions may be obtained based on minimizing a difference between 1) a product of the decomposition weights and the corresponding Zernike polynomials and 2) the results of the integrating the local phase difference for a plurality of local pulse coordinates around a center of each pulse as described herein.

This may allow obtaining the decomposition weights in an efficient manner by an optimization method, for example, by a least square optimization method. This may allow parallelization of the calculations that may be needed for obtaining the decomposition weights.

In some examples, the at least one laser parameter comprises a configuration for a first optical component for applying each of the laser pulses, such as to adjust an amplitude and/or a phase of that laser pulse to at least partially compensate an inhomogeneous refractive index of the substrate of the mask. For example, a corresponding repair apparatus may comprise a pulse shaping unit, which may adapt the pulse shape of each individual laser pulse, e.g., based on the refractive index map, in particular based on the local OPD and/or Zernike decomposition weight(s) derived therefrom. In some examples, good results can be achieved using only less than the ten lowest Zernike orders.

Hereby it may be possible to use the first optical component to counter the effect of the inhomogeneous refractive index to the laser pulses. Using such a first optical component may allow to decouple the problem of determining laser parameters and/or positions to compensate an error of the mask from the effects on the laser pulses created by the inhomogeneous refractive index. In these examples, the complexity of determining the correct positions and/or laser parameters may be reduced. This will be detailed with reference to FIG. 5 below.

In a second example, a method is provided for correcting an error of a mask using a plurality of laser pulses on the substrate of the mask. The method may comprise receiving at least one laser parameter of the plurality of laser pulses and receiving a refractive index map of the substrate of the mask. Further, a local optical path difference, OPD, may be determined based on the at least one laser parameter, wherein the local OPD is caused by deviations in the refractive index map from an average refractive index of the substrate of the mask. In some examples, the local OPD may be used to determine pulse positions and/or parameters as described herein.

The determination of such a local OPD, preferably in the form of lowest order Zernike (or other polynomial) decomposition weights, greatly facilitates the correction of errors in a mask using laser pulses. Specifically, it allows a good compromise, taking into account the refractive index map at reasonable computation costs. The refractive index variation at each position can be taken into account, but at a level of abstraction and data reduction that speeds up the optimization of pulse coordinates and/or parameters by a large extent.

Notably, aspects outlined herein with reference to other examples may also be combined with the second example.

The refractive index map of the substrate of the mask may generally be related to the plurality of positions and/or the plurality of second positions. The refractive index map of the substrate of the mask may be defined for each position of the plurality of positions and/or of the plurality of second positions.

The refractive index map of the substrate of the mask may be related to a plurality of positions such that the refractive index map allows to determine the refractive index value at each of the plurality of positions, for example, by interpolation. In other examples, the refractive index map may have a higher resolution than a resolution of the plurality of positions. In these examples, for each position of the plurality of positions the refractive index is thus defined by the refractive index map.

In a third example, a computer program is provided. The computer program comprises instructions which, when the computer program is executed by a computer, cause the computer to carry out the method of the first and/or second example described herein. In a fourth example, an apparatus for correcting an error of a mask having an inhomogeneous refractive index is provided. The device comprises means for receiving a refractive index map of the substrate of the mask. Further, the device comprises means for receiving mask error information and means for determining at least one first laser parameter for each of a plurality of laser pulses and/or a plurality of positions. The determining may be based on the refractive index map and/or the mask error information.

As detailed above and as will be further detailed below, such an apparatus may enable correction of errors on masks which have an inhomogeneous refractive index. In a fifth example, an apparatus for correcting an error of a mask is provided. The apparatus comprises a laser source for directing a plurality of laser pulses on a plurality of corresponding positions on the substrate of the mask. The apparatus may further comprise means for receiving at least one first individual laser parameter for each laser pulse of the plurality of laser pulses to be applied at a plurality of corresponding positions on the substrate of the mask. Further, the apparatus may comprise a pulse shaping unit. The pulse shaping unit may be adapted for adapting each laser pulse of the plurality of laser pulses according to the at least one first individual laser parameter for the respective laser pulse.

The apparatus according to the fifth example may allow to individually modify each laser pulse of the plurality of laser pulses for each corresponding position on the substrate of the mask. This may allow using a fixed setting of the laser source while individually modifying each individual pulse. This may increase the throughput of the system and/or simplify determination of the parameters of the plurality of laser pulses. The apparatus according to the fifth example will be further detailed below with reference to FIG. 5.

Any apparatus outlined herein may comprise means to carry out the methods outlined herein, e.g., with reference to the first and second examples.

Generally, the aspects described herein may be used as corresponding steps of a method, as computer code and/or corresponding means of an apparatus, even if not always described that way.

Moreover, the methods, the computer programs and apparatuses described herein may not only be used for masks, but also for any other suitable objects, for example, wafers and the like, computer chips, etc.

The computation steps outlined herein, may be implemented in hardware or software, using one or more special purpose or general purpose computers, or processors.

### DESCRIPTION OF DRAWINGS

The patent or application file contains at least one drawing executed in color. Copies of this patent or patent application publication with color drawings will be provided by the Office upon request and payment of the necessary fee. In order to better understand the aspects described herein and to appreciate their practical applications, the following figures are provided and referenced hereafter. It should be noted that the figures are given as examples only and in n₀ way limit the scope of the invention.

FIG. 1 shows schematically an example of a refractive index map.

FIG. 2A and FIG. B schematically exemplarily show the influence of an inhomogeneous index of refraction on an error correction process.

FIG. 3 shows schematically how the effect of an inhomogeneous refractive index can be described according to an example.

FIG. 4 depicts a schematic block diagram of an exemplary apparatus.

FIG. 5 depicts a schematic block diagram of another exemplary apparatus.

FIG. 6A shows an exemplary representation of an exemplary OPD based in a Zernike decomposition.

FIG. 6B shows error metrics of the Zernike decomposition of FIG. 6A.

FIG. 7 shows an exemplary method according to the first example.

### DETAILED DESCRIPTION

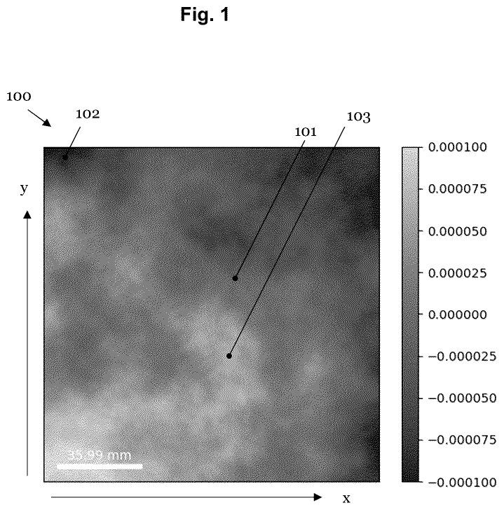

FIG. 1 shows schematically a graphical illustration of an exemplary 2D refractive index map 100. The refractive index map 100 may be a refractive index map of an optical element, for example, a mask substrate.

In FIG. 1, the deviations of the local refractive index from an average refractive index of the substrate of the mask n₀ are shown color coded, as a function of the two-dimensional position (x, y) on the surface. In other words, in FIG. 1 the refractive index map is described in terms of a refractive index difference map Δn(x, y) between the total refractive index map n(x, y) and the average refractive index n₀. In other examples, a refractive index difference map may be a difference, e.g., from a maximum refractive index or a minimum refractive index, such that the difference map may comprise all negative or all positive values. In the example of FIG. 1, the refractive index map describes the local differences between n₀ and the refractive index at a plurality of positions, for example, positions 101, 102, 103. In the example of FIG. 1 the refractive index map is presented in two dimensions x, y in cartesian coordinates. However, other ways to describe the position are of course possible. In particular, the 2D refractive index map may be associated with an average over the entire depth of the substrate, or over the depth of the substrate from its surface to the focal plane, for example. In other examples, the refractive index map may be three-dimensional data which also accounts for depth. For example, a 2D map as shown in FIG. 1 may be associated with a specific plane, e.g., at a certain depth, on or parallel to the substrate's surface (with several maps for different planes then forming a 3D map).

As can be seen for the plurality of positions 101, 102, 103 in FIG. 1, the refractive index shows a variation as function of position x, y. For example, on a first position 101 of the plurality of positions 101, 102, 103, the local refractive index roughly corresponds to the average refractive index n₀. At position 102, the local refractive index is less than the average refractive index n₀, while at position 103 the local refractive index has a higher value than the average refractive index n₀.

In the example of FIG. 1, Δn is smaller than 10-4. However, in other regions of the same mask substrate or in different masks or different (optical) elements, the magnitude of the variations may be different.

In some examples, the map may comprise at least two data points with coordinates having a distance between them of at least 40 mm, at least 80 mm, at least 120 mm or at least 140 mm. In some examples, the data points of a refractive index map span essentially across the entire substrate surface.

In the following, the effect of a local variation in a refractive index on a laser pulse is described, for example, a laser pulse used for correcting an error of a mask.

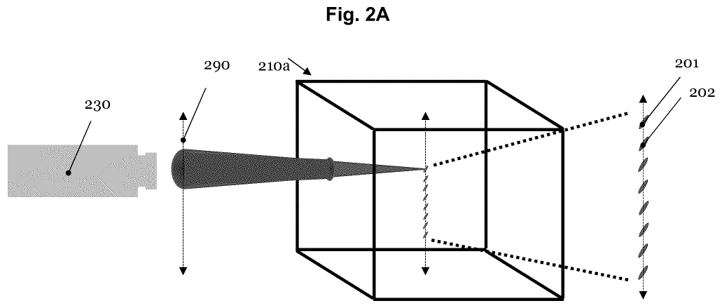

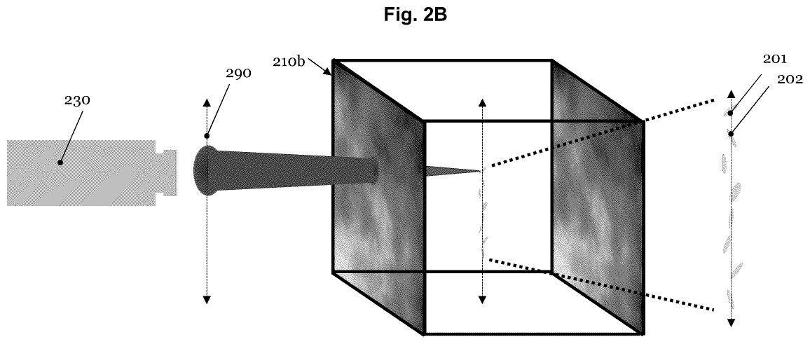

FIG. 2A and FIG. 2B schematically show the influence of an inhomogeneous index of refraction on an error correction process.

In FIG. 2A and FIG. 2B, a laser source 230 provides a plurality of laser pulses, exemplarily shown as a single pulse. For example, by a beam steering system 290, the plurality of laser pulses is focused on a plurality of positions 201, 202 inside mask substrate 210a, 210b. Additional positions of the plurality of positions are also shown in FIG. 2A and FIG. 2B on the respective axis on the right (not labeled).

In the example of FIG. 2A, mask substrate 210a has a homogenous refractive index, for example refractive index n₀. Laser source 230 may be operated with at least one second laser parameter for each of the plurality of laser pulses emitted by laser source 230. The at least one second laser parameter may be determined based on the mask error information, and an average refractive index n₀ may be used for this calculation.

In the example of FIG. 2A, mask substrate 210a has indeed a homogenous refractive index, resulting in laser foci at the plurality of planned positions at a certain focal depth, with the focus shape at each position consistent for the plurality of positions. For example, an elliptic focus with a specific tilt angle relative to the optical axis is provided. In other words, as there is no variation of the refractive index, all pulses lead to essentially the same result.

We exemplarily refer to application WO 2013/030820 A1 how such second laser parameters (also referred to as “mode signatures”) can be determined for correcting errors of a mask or other optical elements.

FIG. 2B shows the scenario of FIG. 2A, when applied to a mask substrate 210b which has an inhomogeneous refractive index. Exemplarily, a map similar to that shown in FIG. 1 is assumed as a 2D map. As illustrated in FIG. 2B, if the same second laser parameters are used on mask substrate 210b, due to the variations in refractive index, the laser foci may be perturbed compared to FIG. 2A. For example, the foci may not be located in the desired focal depth but at a higher or lower depth, instead. In other examples, the shape of the focus may be perturbed, e.g., it may be more or less elliptical than desired. Still in some examples, the tilt angle may deviate from the planned angle, etc. A similar situation may arise, when the refractive index varies in all three dimensions.

As a result, and as shown in FIG. 2B, the perturbation of the laser foci may counteract the desired error correction leading to a result that is less than optimal. These deviations can be greatly reduced when taking the inhomogeneity of the substrate into account, such that the quality of error correction in masks or optical elements with inhomogeneous refractive index as, for example, mask substrate 210b can be greatly improved. This may be particularly relevant for mask substrate materials for EUV lithographic applications, for example, doped glass for EUV lithographic applications.

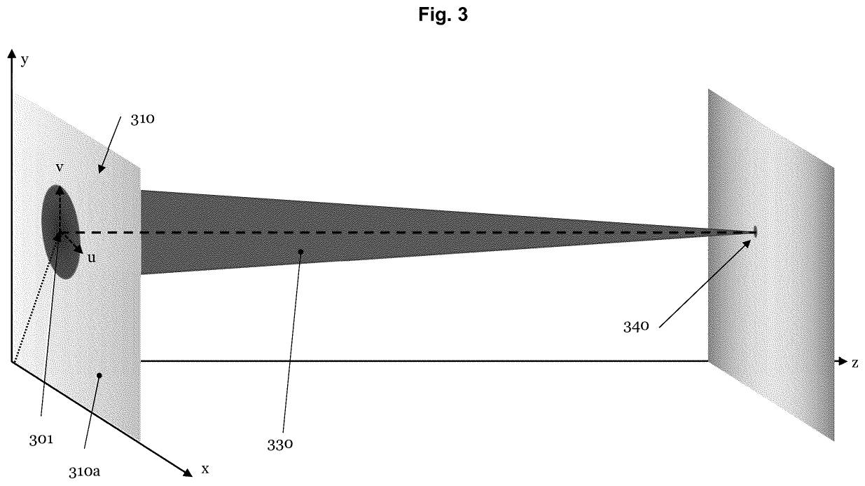

Next, a way to describe the effect of the inhomogeneities on laser pulses is illustrated. FIG. 3 shows schematically how the effect of an inhomogeneous refractive index can be described, according to an example.

As shown in FIG. 3, a laser pulse 330 may impinge on a mask substrate 310 with an inhomogeneous refractive index. As shown in FIG. 3, a first laser pulse impinges onto surface 310a of the substrate of the mask at a first (center) position 301 with coordinates x and y. The description applies similarly to a plurality of other positions xᵢ, yᵢ onto which a pulse may impinge.

The laser at the first position 301 may be focused onto a focus point 340, e.g., at a certain depth within the substrate. The laser pulse 330 may be described in terms of pulse coordinates u and v as known in the art on the surface of the substrate 310a. For example, the pulse may comprise a certain cross section. In the example of FIG. 3, the pulse has a circular cross section, but other cross sections are of course possible. For one or more selected coordinates (u, v), the beam may propagate, following a certain ray, to the focal plane. On its way to the focus, each ray may pick up a varying phase difference and/or optical path difference that may both generally be described as optical path difference (OPD), herein.

The raytracing for determining the OPD may at least in part based on the formula

$$OPD ( x , y ) = \int Δ n ( x , y ) ds ,$$

wherein n₀ is an average refractive index of the substrate of the mask, Δn is the refractive index map describing the deviation of the local refractive index from the average refractive index and wherein the differential ds is the differential along the ray path obtained via the raytracing of the laser pulse.

The raytracing along the laser pulse may be described using the aforementioned one or more selected coordinates (u, v).

The optical phase difference, OPD, may be defined for each location xᵢ, yᵢ. The OPD for a plurality of locations may be described in tensor form in (x, y|u, v) space as OPD (x, y|u, v). By obtaining the OPD, the effect of refractive index variations may thus be described. This description may then allow a compensation of the effects due to the OPD. To illustrate and as detailed below, the OPD may be decomposed into a set of Zernike polynomial coefficients that characterize specific aberration terms such as tilt, defocus, astigmatism, coma, and spherical aberration. These decomposition weights may be used to determine the at least one first laser parameter by quantifying the expected deviation from ideal pulse behavior at each position, for example, by calculating focal depth shifts from the defocus coefficient or lateral focal position shifts from the tilt coefficients. This may then allow to compensate these effects due to the OPD.

In the following, we describe how the knowledge about the refractive index of the substrate of the mask can be used to improve the error correction.

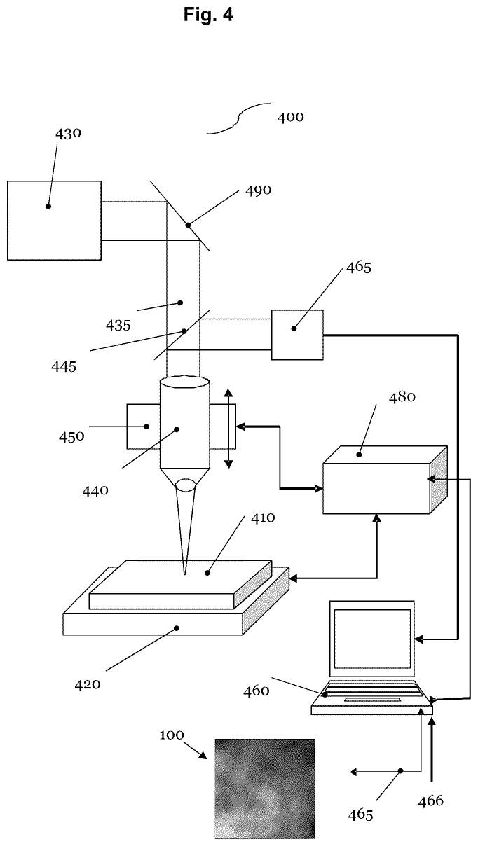

FIG. 4 depicts a schematic block diagram of an apparatus 400 according to an example. The apparatus 400 can be used to correct errors of a mask, for example, the mask of FIG. 1. The apparatus 400 may comprise a chuck 420 which may be movable in three dimensions and/or three angles. The substrate of the mask 410 may be fixed to the chuck 420 by using various techniques, such as for example clamping. The apparatus 400 may include a laser source 430 which may produce a laser pulses 435. The laser source 430 may comprise a pulse generation unit, such as a Ti:Sapphire laser or Yb:HR:HHG laser and may be able to generate laser pulses of a variable duration. For example, the laser source 430 may comprise a pulse duration control module, which may include a pulse stretcher or compressor based on dispersive elements or chirped mirrors. The pulse duration may be as low as 10 fs but may also be increased up to 100 ps, e.g., in steps or continuously. However, other pulse durations are possible as well. The pulse energy of the light pulses generated by the laser source 430 can also be adjusted across a wide range, for example, reaching from 0.01 mJ per pulse up to 10 mJ per pulse. For example, the laser source 430 may comprise a pulse energy control module, which may include variable attenuators, beam splitters with adjustable splitting ratios, and/or an adjustable pump power control for the gain medium. Further, the repetition rate of the laser pulses may comprise the range from 1 Hz to 10 MHz. In some embodiments, the light pulses may be generated by a Ti:Sapphire laser operating at a wavelength of 800 nm. In other embodiments, the light pulses may be generated by a Yb HR:HHG laser. However, the methods described in the following are not limited to these values and this laser type. Principally, all laser types may be used, in particular laser types having a photon energy which is smaller than a band gap of the mask or the substrate of the mask 410 (or of any other element treated by the apparatus) and/or which are able to generate pulses with durations in the femtosecond range. Therefore, for example, Nd:YAG laser or dye laser systems may also be used. The apparatus 400 may also comprise more than one laser source 430 (not shown in FIG. 4). The laser pulses may be adapted such that the substrate of the mask is essentially transparent for the pulse wavelength. However, the laser pulses may be focused and have a sufficiently high density that, at a desired depth, a certain build-up occurs, such that a permanent material change is achieved, e.g., a local expansion of material that may depend on the focal shape.

In the example for FIG. 4, a steering mirror or steering system 490 directs the laser pulses 435 into a focusing objective 440. The objective 440 focuses the laser pulses 435 into the substrate of the mask 410. Properties of the apparatus 400, for example, parameters of the applied objectives and laser parameters may be as those disclosed in WO 2013/030820 A1, for example. However, other parameters are also possible.

The apparatus 400 may also include a controller 480 and a computer system 460 which manage the translations and/or angles of the positioning stage of the chuck 420 and/or of the objective, such that the relative position may be controlled. In some examples, the controller 480 and the computer system 460 may control the translation of the objective 440 perpendicular to the plane of the chuck 420 (z direction). The relative x, y position may in turn be controlled via the position of the chuck. It should be further noted that manual positioning stages can also be used for the movement of the substrate of the mask 410 to the target location of the laser pulses 435 in the x, the y and the z directions and/or the objective 440 may have manual positioning stages for a movement in three dimensions, for example, stage 450 which may be motorized. Other configurations to allow for a relative movement between the substrate of the mask 410 and the laser source 430 are possible as well.

Apparatus 400 may also provide an optional viewing system including a camera 465, such as a CCD (charge-coupled device) camera which may receive light from an illumination source via dichroic mirror 445. The camera 465 may have one or more sensors, e.g., one or more CCD sensors, each having an array of individually addressable sensing elements for capturing images of the mask 410. Light reflected from the mask 410 passes the objective 440 and is reflected by the dichroic mirror 445 towards the camera 465. The viewing system may facilitate navigation of the substrate of the mask 410.

In one example, the apparatus 400 comprises means 465 for receiving a refractive index map 100 of the substrate of the mask. Means 465 may comprise a storage device, a network connection, and a network interface card or communication interface, etc. The refractive index map 100 of the substrate of the mask may be the refractive index map discussed with respect to FIG. 1. The apparatus 400 may further comprise means 466 for receiving mask error information, for example, as part of computer system 460 or a different system (not shown). Means 466 may comprise a storage device, a network connection, and a network interface card or communication interface, etc. Based on the refractive index map and the mask error information, the apparatus may determine at least one first laser parameter for each of a plurality of laser pulses and/or a plurality of positions. This determining may be carried out by computer system 460 or a different system (not shown).

The apparatus 400 may then apply the plurality of laser pulses with the at least one first laser parameter for each pulse from the laser source 430 on the plurality of positions on the substrate of the mask 410. The application of the plurality of laser pulses may be achieved through coordinated control by computer system 460 and/or controller 480. For example, computer system 460 may send commands to controller 480 specifying the at least one first laser parameter and optionally the at least one second laser parameter for each pulse, for example, parameters such as pulse energy, pulse duration, focal depth etc. Controller 480 may then translate these commands into control signals for the laser source 430, configuring the pulse generation unit, energy control module, and duration control module accordingly. Simultaneously or in coordination, controller 480 may control the positioning system of chuck 420 and/or steering mirror 490 to position the substrate such that each pulse is directed to its designated position from the plurality of positions. In embodiments with a pulse shaping unit, computer system 460 or controller 480 may additionally send configuration commands to the pulse shaping unit to adjust the wavefront of each individual pulse etc. The application of the plurality of laser pulses may at least partially correct an error of the mask 410. By taking into account the refractive index map 100 when determining the at least one first laser parameter for each of a plurality of laser pulses and/or the plurality of positions, the correction of the error of the mask may be improved compared to solutions which do not take the refractive index inhomogeneities of the substrate of the mask 410 into account.

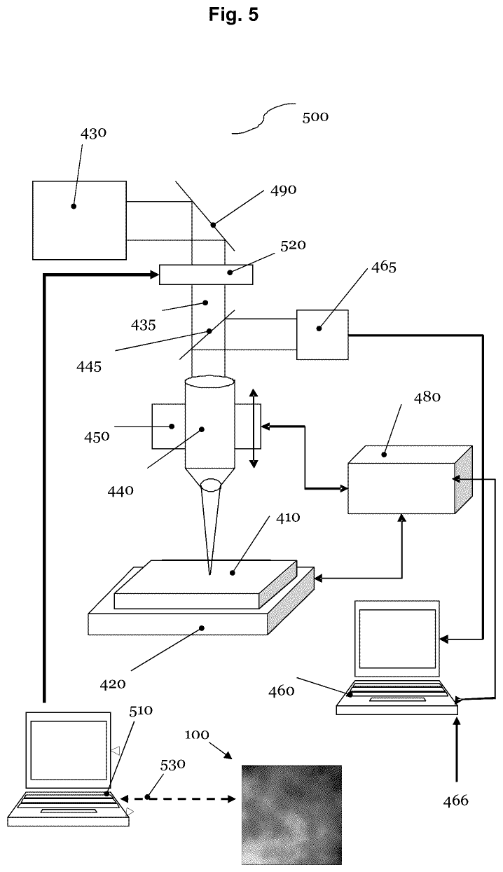

FIG. 5 depicts a schematic block diagram of another exemplary apparatus 500. The apparatus 500 may correspond to the apparatus 400 described in FIG. 4 unless described otherwise below.

Computer 460 of apparatus 500 may be adapted for receiving and processing a refractive index map as outlined with reference to FIG. 4. However, this is not necessarily the case. Instead, computer 460 may simply be adapted to control the application of pulses that may be determined as in the prior art, and/or simply according to a pulse map externally provided to computer 460.

In addition to the components outlined with reference to FIG. 4, the apparatus 500 may comprise a pulse shaping unit 520. Notably, also the apparatus of FIG. 4 may comprise such pulse shaping unit, albeit not shown there.

The pulse shaping unit 520 may be adapted to vary each individual pulse. For example, the pulses may thus be corrected for the respective refractive index variation at the respective pulse position.

To allow that control, apparatus 500 may comprise means for receiving at least one first individual laser parameter for each laser pulse of the plurality of laser pulses to be applied at a plurality of corresponding positions on the substrate of the mask. The means may be a computer system 510, which may or may not be identical to computer system 460. Computer system 510 may then control pulse shaping unit 520 accordingly. Pulse shaping unit 520 may, for example, comprise a lens, adaptive optics, such as an adaptive or deformable mirror, etc. For example, a deformable mirror may be used that provides a stroke of up to about 90 μm deformation and/or a bandwidth of about 2 kHz, In some embodiments, a wave-front sensor, for example, a Shack-Hartmann sensor may be used to monitor properties of the plurality of laser pulses. In some examples, a sensor may be used that provides an absolute RMS accuracy of about λ/100, a repeatability of about λ/100 or better, a pupil size of about 5 mm×5 mm or more, and/or a frame rate of 100 Hz or more. The monitored properties may allow determining if a laser pulse has the at least one first individual laser parameter.

In addition or alternatively, computer system 510 may be adapted to receive a refractive index map 100, e.g., via a suitable interface 530. Based thereon, computer system 510 may determine the at least one first individual laser parameter for each laser pulse of the plurality of laser pulses to be applied at a plurality of positions.

As outlined, computer system 510 and computer system 460 may be realized by a single computer system. The pulse shaping unit 510 may also be controlled via a controller as intermediary to the respective computer, which may be controller 480 or a separate controller.

The pulse shaping unit 520 of FIG. 5 may generally be adapted for adapting each laser pulse of the plurality of laser pulses according to the at least one first individual laser parameter for the respective laser pulse. The pulse shaping unit 510 may adjust an amplitude and/or a phase of each individual laser pulse. This adjustment may be carried out based on decomposition weights Cᵢ for Zernike polynomials Zᵢⱼ of a local OPD. An example for a decomposition will be detailed below. However, the adjustment may also be carried out based on other representations of the effect of the inhomogeneities of the refractive index of the substrate of the mask.

Thus, in one example, the pulse shaping unit 520 may be operated to at least partially compensate for the effects of an inhomogeneous refractive index of the substrate of the mask. In some examples, apparatus 500 may be used to improve a process agnostic to the refractive index map 100 of a surface, for example, an error correction process carried out by computer system 460 of FIG. 5 which is not based on the refractive index map. In the following we describe how representation by a Zernike polynomial basis may be advantageously used, for example, in the apparatus 400 of FIG. 4 and apparatus 500 of FIG. 5.

To represent an image I by use of decomposition weights Cᵢ for Zernike polynomials, the optimization problem for determining the decomposition weights Cᵢ may be formulated as follows:

$$min {‖ {Z}_{ij} \cdot {C}_{i} - {I}_{j} ‖}_{F} .$$

Here, F denotes the Frobenius norm; Zᵢⱼ are Zernike polynomials of order i with image dimension index j. Ij are image pixels and Cᵢ are the decomposition weights of the Zernike polynomials.

For the decomposition weights Cᵢ obtained by this optimization process, the achieved accuracy may be described in terms of error metrics. Namely, the following error metrics may be used:
RSS=Σⱼ(Iⱼ−Zⱼᵢ·Cᵢ)², where RSS denotes a residual sum of squares.

Further, the following metric may be used:
TSS=Σⱼ(Iⱼ− [symbol] Iⱼ [symbol] )², where TSS denotes the total sum of squares or variance.

Then the coefficient of determination, R², may be defined as:

$${R}^{2} = 1 - \frac{RSS}{TSS} .$$

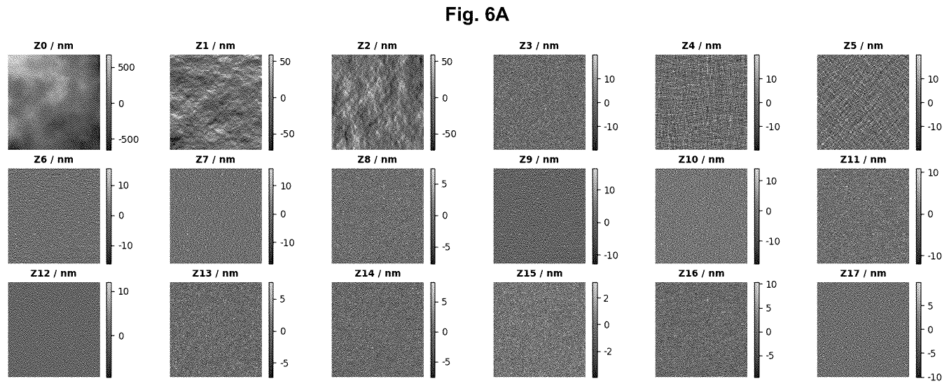

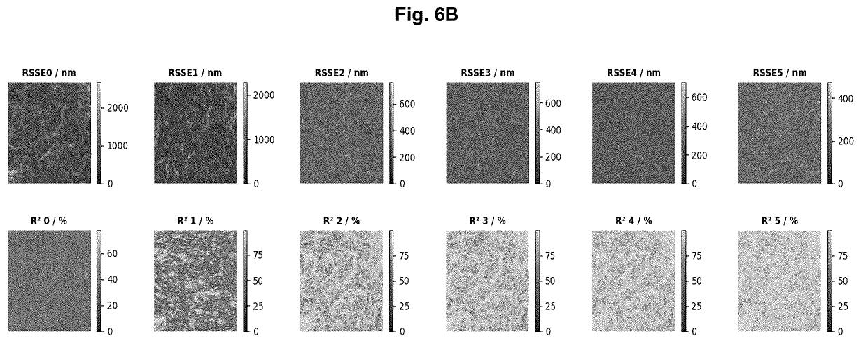

In some embodiments, these measures may be used to determine to which order the decomposition in Zernike polynomials may be required to achieve a desired level of accuracy. This will be further detailed below with reference to FIGS. 6A and 6B.

FIG. 6A shows a representation of the OPD residuals when using an approximation based on a Zernike decomposition using polynomials up to different orders denoted by Z0, Z1, Z2, . . . to Z17. For example, in the plot denoted by Z0, that optical path difference of the experimental refractive index map that remains after approximating it by the 0-th order Zernike polynomial is shown (this may be seen as a remaining error when using only a Z0-approximation). The unit in this graph is the optical path difference in nm. In the plot denoted with Z1, the remaining error when using a Z0 and Z1 approximation is shown. As can be seen, already with an approximation up to Z2, a very good approximation can be achieved, with an error below ±60 nm. This error can be reduced to below ±20 nm and +10 nm, by using an approximation up to Z3 or Z8, respectively.

In this particular example, thus, an approximation up to Z2, Z3 or Z8 may be optimal, depending on the level of error that is considered acceptable.

FIG. 6B shows error metrics of the Zernike decomposition shown in FIG. 6A. The top row of FIG. 6B shows residual sum of squares error, RSS, when using Zernike polynomials up to order 0, 1, . . . 5. The bottom row of FIG. 6B shows the corresponding coefficients of determination, R². As can be seen from top and bottom rows of FIG. 6B, the accuracy of the representation of the refractive index inhomogeneity by decomposition into Zernike polynomials increases with the order of the Zernike polynomials. For some examples, already relatively few coefficients, for example up to 4th order, for example up to 5th order, for example up to 6th order, for example up to 7th order, may be suited for a representation of the inhomogeneity with a desired accuracy.

Decomposition weights Cᵢ up to an order i which provides sufficient accuracy for the Zernike polynomials Zᵢⱼ may be used, e.g., for optimization of pulse parameters and/or positions as described herein. Also, the decomposition wights up to Cᵢ may be directly used for the pulse shaping unit 520 explained with reference to FIG. 5 which may be configured based on the decomposition weights to compensate for them. This may simplify the optics and/or control circuitry for the pulse shaping unit 520 and/or increase throughput of the apparatus 500.

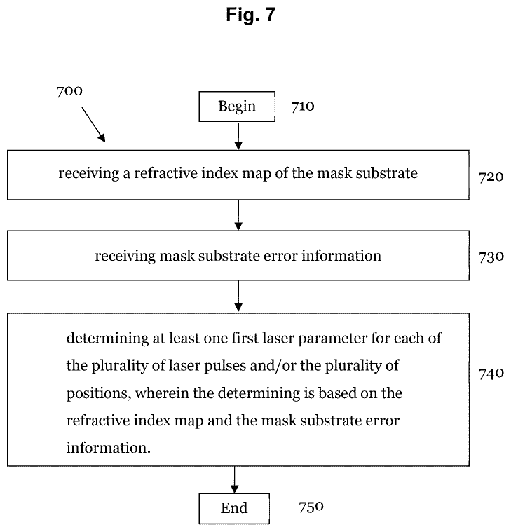

FIG. 7 shows a method according to the first example. The method 700 for correcting an error of a mask using a plurality of laser pulses applied on a plurality of positions on the substrate of the mask begins at 710. In step 720, a refractive index map of the substrate of the mask is received. In step 730, mask error information is received. The mask error information may comprise deformation information and/or alignment information, e.g., as described herein.

In step 740, at least one first laser parameter for each of the plurality of laser pulses and/or the plurality of positions is determined. For example, a first laser parameter resulting in a laser focus as shown in FIG. 2A and FIG. 2B is determined. The determining in step 740 may be based on the refractive index map and the mask error information. By taking into account both the refractive index map and the mask error information, at least a partial correction of the error of the mask may be achieved even for substrates of masks with inhomogeneous material properties, in particular inhomogeneous refractive index.

In some examples, for a first set of second laser parameters (e.g., a first focal shape at a certain depth), a first set of optimized pulse positions may be determined. For a second set of second laser parameters (e.g., a second focal shape at a certain (different) depth), a second set of optimized pulse positions may be determined. Generally, for an n-th set of second laser parameters, an n-th set of optimized pulse positions may be determined. Thus, various pulse types may be uniformly applied to the substrate of the mask, such that they, in combination, optimally repair the error, taking into account the refractive index map.

The aspects described in this document can be computer-implemented and/or implemented using hardware and/or software. Whether aspects are implemented as hardware or software depends upon the particular application and design constraints imposed on the overall system. By way of example, an element, or any portion of an element, or any combination of elements can be implemented as a processing system that can include one or more processors. Examples of processors include microprocessors, microcontrollers, graphics processing units (GPUs), central processing units (CPUs), application processors, digital signal processors (DSPs), reduced instruction set computing (RISC) processors, systems on a chip (SoC), baseband processors, field programmable gate arrays (FPGAs), programmable logic devices (PLDs), state machines, gated logic, discrete hardware circuits, and other suitable hardware configured to perform the various functionality described throughout this disclosure. One or more processors in the processing system may execute software. Software shall be construed broadly to mean instructions, instruction sets, code, code segments, program code, programs, subprograms, software components, applications, software applications, software packages, routines, subroutines, objects, executables, threads of execution, procedures, functions, etc., whether referred to as software, firmware, middleware, microcode, hardware description language, or otherwise.

Accordingly, in one or more exemplary embodiments, the functions described in this document can be implemented in hardware, software, or any combination thereof. If implemented in software, the functions may be stored on or encoded as one or more instructions or code on a computer-readable medium. Computer-readable media includes computer storage media. Storage media can be any available media that can be accessed by a computer. By way of example, and not limitation, such machine-readable media or computer-readable media can include a random-access memory (RAM), a read-only memory (ROM), an erasable programmable ROM (EPROM), an electrically erasable programmable ROM (EEPROM), FPGA, optical disk storage (e.g., CD, DVD, Blu-ray disc), a flash storage device, a solid state drive, magnetic disk storage, other magnetic storage devices, combinations of the aforementioned types of computer-readable media, or any other medium that can be used to store computer executable code in the form of instructions or data structures that can be accessed by a computer.

A controller (e.g., 480) can include, e.g., a computer, a computing entity, or a processor that can adapt one or more system parameters of the apparatus (e.g., the translations and/or angles of the positioning stage of the chuck 420 and/or of the objective) to cause the apparatus to perform the methods described in this document. For example, the controller can include a storage device that stores a computer program including instructions that when executed enable the controller to control the apparatus to perform the processes described in this document.

In some implementations, the computer system 460, 510 can include one or more data processors and one or more storage devices. The one or more data processors can be configured to process the data described herein, e.g., according to at least some steps of the methods described herein. The one or more storage devices can store at least a part of the instructions comprised in a computer program as described herein, preferably all instructions of the computer program, one or more refractive index maps, and/or mask error information. The one or more data processors can be configured to execute one or more programs that include a plurality of instructions according to the principles described above. Each data processor can include one or more processor cores, and each processor core can include logic circuitry for processing data. For example, a data processor can include an arithmetic and logic unit (ALU), a control unit, and various registers. Each data processor can include cache memory. Each data processor can include a system-on-chip (SoC) that includes multiple processor cores, random access memory, graphics processing units, one or more controllers, and one or more communication modules. Each data processor can include millions or billions of transistors.

The processing of data described in this document, such as (i) determining at least one first laser parameter for each of the plurality of laser pulses and/or the plurality of positions, based on the refractive index map and the mask error information, (ii) determining, for each position (x, y) of the plurality of positions and/or of the second plurality of positions, a local optical path difference, OPD, (iii) integrating the local phase difference for a plurality of local pulse coordinates around a center of each pulse, acquired by propagation from that local pulse coordinate to a corresponding focal depth z0 within the substrate of the mask, (iv) raytracing, etc., can be carried out using one or more computers, which can include one or more data processors for processing data, one or more storage devices for storing data, and/or one or more computer programs including instructions that when executed by the one or more computers cause the one or more computers to carry out the processes. The one or more computers can include one or more input devices, such as a keyboard, a mouse, a touchpad, and/or a voice command input module, and one or more output devices, such as a display, and/or an audio speaker.

In some implementations, the one or more computing devices can include digital electronic circuitry, computer hardware, firmware, software, or any combination of the above. The features related to processing of data can be implemented in a computer program product tangibly embodied in an information carrier, e.g., in a machine-readable storage device, for execution by a programmable processor; and method steps can be performed by a programmable processor executing a program of instructions to perform functions of the described implementations. Alternatively or in addition, the program instructions can be encoded on a propagated signal that is an artificially generated signal, e.g., a machine-generated electrical, optical, or electromagnetic signal, that is generated to encode information for transmission to suitable receiver apparatus for execution by a programmable processor.

A computer program can be written in any form of programming language, including compiled or interpreted languages, and it can be deployed in any form, including as a stand-alone program or as a module, component, subroutine, or other unit suitable for use in a computing environment.

For example, the one or more computers can be configured to be suitable for the execution of a computer program and can include, by way of example, both general and special purpose microprocessors, and any one or more processors of any kind of digital computer. Generally, a processor will receive instructions and data from a read-only storage area or a random access storage area or both. Elements of a computer system include one or more processors for executing instructions and one or more storage area devices for storing instructions and data. Generally, a computer system will also include, or be operatively coupled to receive data from, or transfer data to, or both, one or more machine-readable storage media.

In some implementations, the processes described above can be implemented using software for execution on one or more mobile computing devices, one or more local computing devices, and/or one or more remote computing devices (which can be, e.g., cloud computing devices). For instance, the software forms procedures in one or more computer programs that execute on one or more programmed or programmable computer systems, either in the mobile computing devices, local computing devices, or remote computing systems (which may be of various architectures such as distributed, client/server, grid, or cloud), each including at least one processor, at least one data storage system (including volatile and non-volatile memory and/or storage elements), at least one wired or wireless input device or port, and at least one wired or wireless output device or port.

In some implementations, the software may be provided on a medium readable by a general or special purpose programmable computer or delivered (encoded in a propagated signal) over a network to the computer where it is executed. The functions can be performed on a special purpose computer, or using special-purpose hardware, such as coprocessors. The software can be implemented in a distributed manner in which different parts of the computation specified by the software are performed by different computers. Each such computer program is preferably stored on or downloaded to a storage media or device (e.g., solid state memory or media, or magnetic or optical media) readable by a general or special purpose programmable computer, for configuring and operating the computer when the storage media or device is read by the computer system to perform the procedures described herein. The inventive system can also be considered to be implemented as a computer-readable storage medium, configured with a computer program, where the storage medium so configured causes a computer system to operate in a specific and predefined manner to perform the functions described herein.

The embodiments of the present invention that are described in this specification and the optional features and properties respectively mentioned in this regard should also be understood to be disclosed in all combinations with one another. In particular, in the present case, the description of a feature comprised by an embodiment-unless explicitly explained to the contrary-should also not be understood such that the feature is essential or indispensable for the function of the embodiment.

### FURTHER EXAMPLES

Example 1. A method (700) for correcting an error of a mask using a plurality of laser pulses applied on a plurality of positions on a substrate of the mask, the method comprising:
receiving (720) a refractive index map of the mask substrate,
receiving (730) mask error information,
determining (740) at least one first laser parameter for each of the plurality of laser pulses and/or the plurality of positions,
wherein the determining is based on the refractive index map and the mask error information.

Example 2. The method of example 1, further comprising:
applying the plurality of laser pulses with the at least one first laser parameter for each pulse on the plurality of positions on the substrate of the mask.

Example 3. The method of example 1 or example 2, further comprising:
receiving at least one second laser parameter for each of the plurality of laser pulses, and
wherein the at least one first laser parameter and/or the plurality of positions is further determined based on the at least one second laser parameter.

Example 4. The method of any of examples 1-3, further comprising:
receiving a second plurality of positions on the substrate of the mask, and
wherein the plurality of positions and/or the at least one first laser parameter is further determined based on the second plurality of positions.

Example 5. The method of any of examples 1-4, wherein determining the at least one first laser parameter further comprises:
determining, for each position (x, y) of the plurality of positions and/or of the second plurality of positions, a local optical path difference, OPD, wherein the local OPD is caused by deviations in the refractive index map from an average refractive index of the substrate of the mask.

Example 6. The method of example 5, wherein the determining the local OPD includes raytracing of a laser pulse to be applied on the respective position based on the refractive index map.

Example 7. The method of example 5 or 6, wherein for each position (x, y), the determining of the local OPD includes integrating the local phase difference for a plurality of local pulse coordinates around a center of each pulse, acquired by propagation from that local pulse coordinate to a corresponding focal depth z₀ within the substrate of the mask.

Example 8. The method of example 6 or example 7, wherein the raytracing for determining the OPD is at least in part based on the formula

$$OPD ( x , y ) = \int Δ n ( x , y ) ds ,$$

wherein n₀ is an average refractive index of the substrate of the mask,
Δn is the refractive index map describing a deviation of a local refractive index from the average refractive index and
wherein the differential ds is the differential along the ray path obtained via the raytracing of the laser pulse.

Example 9. The method of any of examples 5-8, wherein each local OPD comprises a set of decomposition weights (Ci) for Zernike polynomials (Zij).

Example 10. The method of any of examples 1-9, further comprising:
wherein the at least one laser parameter comprises a configuration for a first optical component for applying each of the laser pulses, such as to adjust an amplitude and/or a phase of that laser pulse to at least partially compensate an inhomogeneous refractive index of the substrate of the mask.

Example 11. A method for correcting an error of a mask using a plurality of laser pulses on the substrate of the mask, the method comprising:
receiving at least one laser parameter of the plurality of laser pulses,
receiving a refractive index map of the substrate of the mask,
determining, for a plurality of positions (x, y) on the substrate of the mask, a local optical path difference, OPD, based on the at least one laser parameter, wherein the local OPD is caused by deviations in the refractive index map from an average refractive index of the substrate of the mask.

Example 12. A computer program comprising instructions which, when the computer program is executed by a computer, cause the computer to carry out the steps of the method of any of examples 1-11.

Example 13. An apparatus (400) for correcting an error of a mask having an inhomogeneous refractive index, the device comprising:
means for receiving a refractive index map of a substrate of the mask,
means (466) for receiving mask error information,
means for determining at least one first laser parameter for each of a plurality of laser pulses and/or a plurality of positions,
wherein the determining is based on the refractive index map and the mask error information.

Example 14. An apparatus (500) for correcting an error of a mask, comprising:
a laser source (430) for directing a plurality of laser pulses on a plurality of corresponding positions on a substrate of the mask;
means (510) for receiving at least one first individual laser parameter for each laser pulse of the plurality of laser pulses to be applied at a plurality of corresponding positions on the substrate of the mask;
a pulse shaping unit (520) adapted for adapting each laser pulse of the plurality of laser pulses according to the at least one first individual laser parameter for the respective laser pulse.

Example 15. The apparatus of example 13 or 14, further comprising means to carry out the method according to any of examples 1-11.

A number of embodiments of the invention have been described. Nevertheless, it will be understood that various modifications may be made without departing from the spirit and scope of the invention. Accordingly, other embodiments are within the scope of the following claims.

What is claimed is:

1. A method for correcting an error of a mask using a plurality of laser pulses applied on a plurality of positions on a substrate of the mask, the method comprising:
receiving a refractive index map of the mask substrate,
receiving mask error information,
determining at least one first laser parameter for each of the plurality of laser pulses and/or the plurality of positions,
wherein the determining is based on the refractive index map and the mask error information.

2. The method of claim 1, further comprising:
applying the plurality of laser pulses with the at least one first laser parameter for each pulse on the plurality of positions on the substrate of the mask.

3. The method of claim 1, further comprising:
receiving at least one second laser parameter for each of the plurality of laser pulses, and
wherein the at least one first laser parameter and/or the plurality of positions is further determined based on the at least one second laser parameter.

4. The method of claim 1, further comprising:
receiving a second plurality of positions on the substrate of the mask, and
wherein the plurality of positions and/or the at least one first laser parameter is further determined based on the second plurality of positions.

5. The method of claim 1, wherein determining the at least one first laser parameter further comprises:
determining, for each position of the plurality of positions, a local optical path difference (OPD) wherein the local OPD is caused by deviations in the refractive index map from an average refractive index of the substrate of the mask.

6. The method of claim 5, wherein the determining the local OPD includes raytracing of a laser pulse to be applied on the respective position based on the refractive index map.

7. The method of claim 5, wherein for each position, the determining of the local OPD includes integrating the local phase difference for a plurality of local pulse coordinates around a center of each pulse, acquired by propagation from that local pulse coordinate to a corresponding focal depth z₀ within the substrate of the mask.

8. The method of claim 6, wherein the raytracing for determining the OPD is at least in part based on the formula
$$OPD ( x , y ) = \int Δ n ( x , y ) ds ,$$
wherein n₀ is an average refractive index of the substrate of the mask,
Δn is the refractive index map describing a deviation of a local refractive index from the average refractive index and
wherein the differential ds is the differential along the ray path obtained via the raytracing of the laser pulse.

9. The method of claim 5, wherein each local OPD comprises a set of decomposition weights for Zernike polynomials.

10. The method of claim 1, further comprising:
wherein the at least one laser parameter comprises a configuration for a first optical component for applying each of the laser pulses, to adjust an amplitude and/or a phase of that laser pulse to at least partially compensate an inhomogeneous refractive index of the substrate of the mask.

11. A method for correcting an error of a mask using a plurality of laser pulses on the substrate of the mask, the method comprising:
receiving at least one laser parameter of the plurality of laser pulses,
receiving a refractive index map of the substrate of the mask,
determining, for a plurality of positions on the substrate of the mask, a local optical path difference, OPD, based on the at least one laser parameter, wherein the local OPD is caused by deviations in the refractive index map from an average refractive index of the substrate of the mask.

12. A non-transitory computer-readable medium comprising instructions which, when the computer program is executed by a computer, cause the computer to carry out the steps of the method of claim 1.

13. A non-transitory computer-readable medium comprising instructions which, when the computer program is executed by a computer, cause the computer to carry out the steps of the method of claim 11.

14. An apparatus for correcting an error of a mask having an inhomogeneous refractive index, the apparatus comprising:
a processor; and
a memory storing instructions that, when executed by the processor, cause the apparatus to:
receive a refractive index map of a substrate of the mask,
receive mask error information, and
determine at least one first laser parameter for each of a plurality of laser pulses and/or a plurality of positions,
wherein the determining is based on the refractive index map and the mask error information.

15. The apparatus of claim 14, further comprising a laser source configured to apply the plurality of laser pulses with the at least one first laser parameter for each pulse on the plurality of positions on the substrate of the mask.

16. The apparatus of claim 14, wherein the apparatus is configured to determine, for each position of a plurality of positions, a local optical path difference (OPD) wherein the local OPD is caused by deviations in the refractive index map from an average refractive index of the substrate of the mask.

17. The apparatus of claim 16, wherein the apparatus is further configured to determine the local OPD by including raytracing of a laser pulse to be applied on the respective position based on the refractive index map.

18. The apparatus of claim 16, wherein for each position, the apparatus is further configured to determine the local OPD by including integrating the local phase difference for a plurality of local pulse coordinates around a center of each pulse, acquired by propagation from that local pulse coordinate to a corresponding focal depth z₀ within the substrate of the mask.

19. The apparatus of claim 17, wherein the raytracing for determining the OPD is at least in part based on the formula
$$OPD ( x , y ) = \int Δ n ( x , y ) ds ,$$
wherein n₀ is an average refractive index of the substrate of the mask,
Δn is the refractive index map describing a deviation of a local refractive index from the average refractive index and
wherein the differential ds is the differential along the ray path obtained via the raytracing of the laser pulse.

20. An apparatus for correcting an error of a mask, comprising a laser source for directing a plurality of laser pulses on a plurality of corresponding positions on a substrate of the mask;
wherein the apparatus is configured to receive at least one first individual laser parameter for each laser pulse of the plurality of laser pulses to be applied at a plurality of corresponding positions on the substrate of the mask; the apparatus further comprising:
a pulse shaping unit adapted for adapting each laser pulse of the plurality of laser pulses according to the at least one first individual laser parameter for the respective laser pulse.
